(19) United States
(12) Patent Application Publication
(10) Pub. No.: US 2026/0005086 A1
(43) Pub. Date: Jan. 1, 2026

(54) Semiconductor Device and Method of Integrating PIC in FOI with Protective Layer over Photonic Region

(71) Applicant: STATS ChipPAC Pte. Ltd., Singapore (SG)

(72) Inventors: Swain Hong Alfred Yeo, Singapore (SG); Kai Chong Chan, Singapore (SG); Linda Pei Ee Chua, Singapore (SG)

(73) Assignee: STATS ChipPAC Pte. Ltd., Singapore (SG)

(21) Appl. No.: 18/760,172

(22) Filed: Jul. 1, 2024

(51) Int. Cl. H01L 23/29; H01L 23/00; H01L 23/48; H01L 23/498; H01L 25/18; H01L 27/144

(52) U.S. Cl. CPC H01L 23/293; H01L 23/481; H01L 23/49827; H01L 25/18; H10F 39/10; H01L 23/49822; H01L 24/24; H01L 2224/24145

(57) ABSTRACT

A semiconductor device has a first interconnect structure with an opening in the first interconnect structure. A PIC is disposed over the first interconnect structure with a photonic region aligned with the opening in the first interconnect structure. A plurality of conductive vias is formed at least partially through the PIC. An interconnect component having a plurality of conductive vias is disposed over the first interconnect structure. A plurality of bumps can be formed over the first interconnect structure. A second interconnect structure is disposed over the PIC and interconnect component. A protective layer is disposed within the opening over the photonic region. An electrical component is disposed over the second interconnect structure. The protective layer can have a dam formed over the PIC and an epoxy material disposed within the dam over the photonic region. Alternatively, the protective layer has an epoxy material disposed over the photonic region.

### FIELD OF THE INVENTION

The present invention relates in general to semiconductor devices and, more particularly, to a semiconductor device and method of integrating a photonic integrated circuit (PIC) in a fan-out interposer (FOI) package with a protective layer over the photonic region.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices may contain multiple electrical components, e.g., one or more semiconductor die and myriad discrete components to support the semiconductor die, disposed on one or more substrates to perform necessary electrical functions. Highly integrated packages with several components are commonly referred to as system-in-package (SiP) modules. SiP modules often have multiple semiconductor die designed to communicate with each other at high bandwidths. Conductive traces and other interconnect structures formed at the package level may be insufficient to support the necessary bandwidth.

Many SiP modules utilize bridge die to facilitate high-bandwidth communication between components. Bridge die are semiconductor die that may have no circuits formed in their active surface but have fine-pitched interconnects formed over them. Bridge die can be disposed between two or more other semiconductor die, then the adjacent semiconductor die are connected to each other through the bridge die to increase the available data bandwidth between them.

Some bridge die include photonic regions. Photonic regions are light-sensitive to add important functionality to the end units. However, photonic regions also add significant design constraints to the semiconductor packages being formed because the photonic region must be exposed to the outside world to allow the intended light stimulus to reach the photonic region. It is important to protect the photonic region during manufacturing, such as encapsulation. Therefore, a need exists for manufacturing methods and device structures that allow the photonic region of embedded bridge die to be protected during manufacturing, and yet exposed or otherwise accessible to light in a final package.

### BRIEF DESCRIPTION OF THE DRAWINGS

FIGS. 1a-1c illustrate a semiconductor wafer with a plurality of semiconductor die separated by a saw street;

FIGS. 2a-2d illustrate a process of forming interconnect component with conductive vias;

FIGS. 3a-3c illustrate a process of forming a PIC with a photoresist layer over the photonic region;

FIGS. 4a-4c illustrate a process of forming another PIC with an epoxy material over the photonic region;

FIGS. 5a-5b illustrate a process of forming another PIC with a prefabricated epoxy block over the photonic region;

FIGS. 6a-6p illustrate a process of disposing the PIC from FIGS. 3a-3c and interconnect component from FIG. 2a-2d over an interconnect structure;

FIGS. 7a-7j illustrate a process of disposing the PIC from FIGS. 4a-4c and interconnect component from FIG. 2a-2d over an interconnect structure;

FIG. 8 illustrates the PIC from FIG. 5b and interconnect component from FIG. 2d over an interconnect structure; and

FIG. 9 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

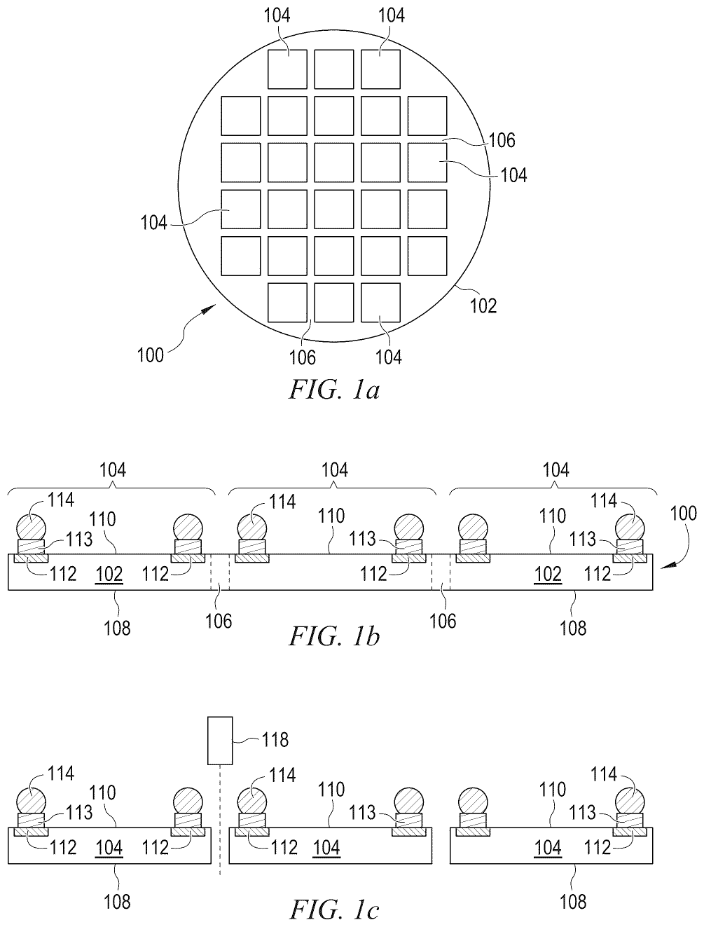

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die or unit (KGD/KGU) post singulation.

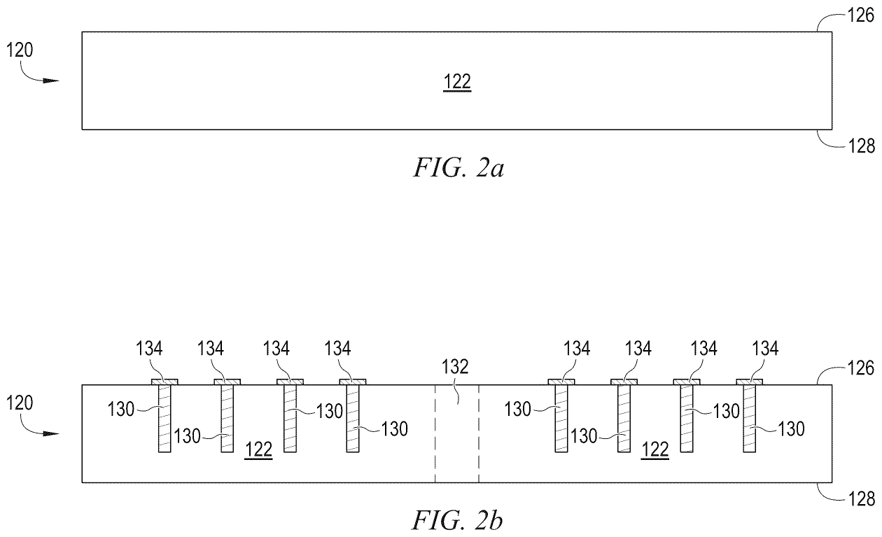

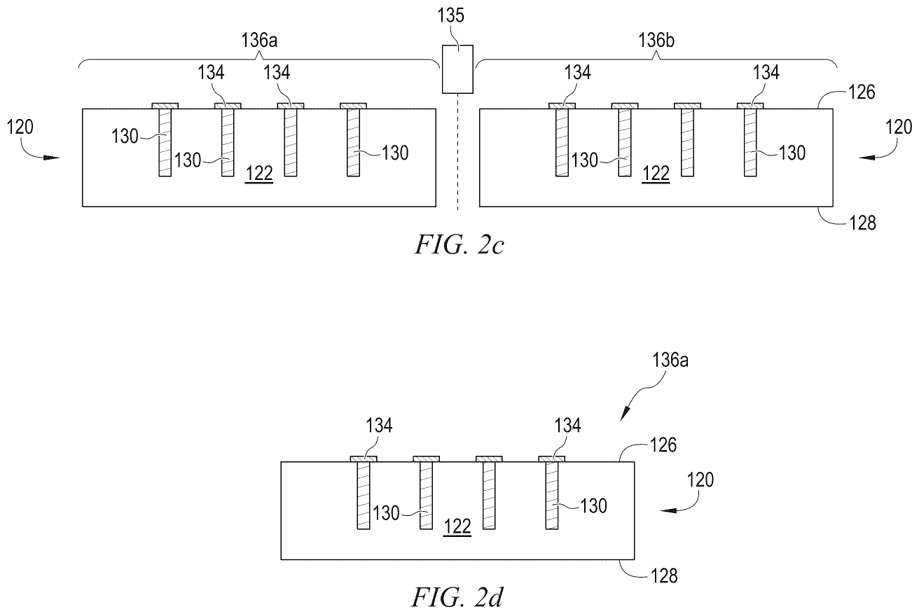

FIGS. 2a-2d illustrate a process of forming an interconnect component/bridge die 136a-136b. FIG. 2a shows a semiconductor wafer 120 with a base substrate material 122, such as silicon, germanium, aluminum phosphide, aluminum arsenide, gallium arsenide, gallium nitride, indium phosphide, silicon carbide, or other bulk material for structural support. Semiconductor wafer 120 has major surface 126 and major surface 128, opposite surface 126. In one embodiment, surface 126 of semiconductor wafer 120 may have no active or passive electrical components, as in a bridge die. Alternatively, a plurality of semiconductor die or electrical components can be formed on active surface 126. Each semiconductor die on semiconductor wafer 120 has a back or non-active surface 128 and active surface 126 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 126 to implement analog circuits or digital circuits, such as digital signal processor (DSP), application specific integrated circuits (ASIC), memory, or other signal processing circuit. The semiconductor die may also contain IPDs, such as inductors, capacitors, and resistors, for RF signal processing.

In FIG. 2b, a plurality of conductive vias 130 is formed from surface 126 at least partially through base material 122. A plurality of vias is formed at least partially through semiconductor wafer 120 using an etching process or by laser direct ablation (LDA). The vias are filled with electrically conductive material, such as Al, Cu, Sn, Ni, Au, Ag, or other suitable electrically conductive material, to form conductive vias 130. Semiconductor wafer 120 includes saw streets 132 for later singulation.

An electrically conductive layer 134 is formed over surface 126 and conductive vias 130 using PVD, CVD, electrolytic plating, electroless plating process, or other suitable metal deposition process. Conductive layer 134 can be one or more layers of Al, Cu, Sn, Ni, Au, Ag, or other suitable electrically conductive material. Conductive layer 134 operates as a redistribution layer (RDL) providing electrical interconnect for conductive vias 130, as well as any active electrical components and passive electrical components on surface 126. Portions of conductive layer 134 can be electrically common or electrically isolated depending on the design and function of electrical components attached thereto.

In FIG. 2c, semiconductor wafer 120 is singulated through saw street 132 using a saw blade or laser cutting tool 135 into individual interconnect component/bridge die 136a and 136b. The individual interconnect component/bridge die 136a-136b can be inspected and electrically tested for identification of KGD/KGU post singulation. FIG. 2d shows interconnect component/bridge die 136a or 136b post singulation.

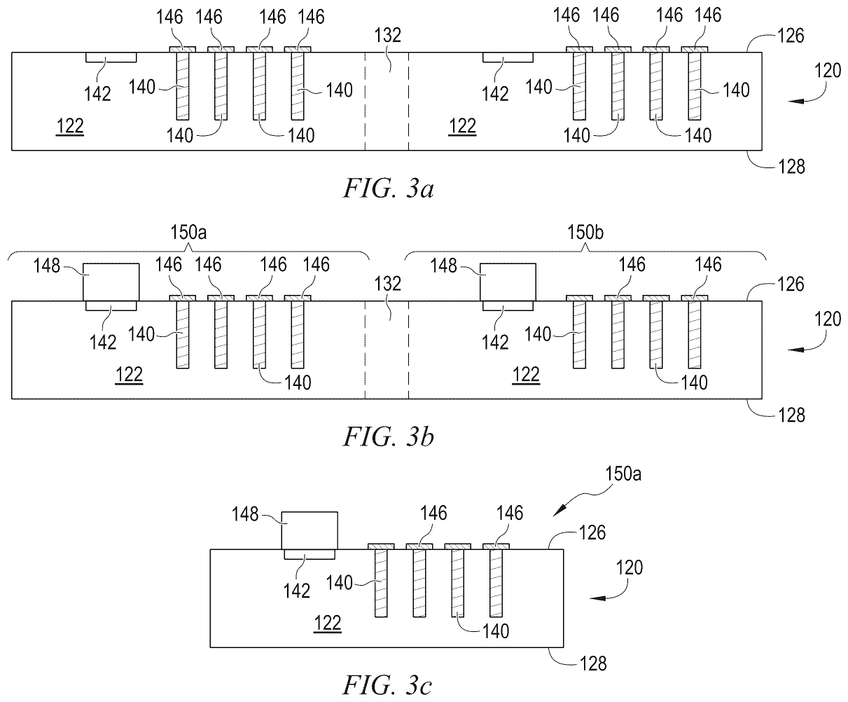

FIGS. 3a-3c illustrate a process of forming a PIC. Continuing from FIG. 2a, a plurality of conductive vias 140 is formed from surface 126 at least partially through base material 122. A plurality of vias is formed at least partially through semiconductor wafer 120 using an etching process or by LDA. The vias are filled with electrically conductive material, such as Al, Cu, Sn, Ni, Au, Ag, or other suitable electrically conductive material, to form conductive vias 140. Components having a similar function are assigned the same reference number. Surface 126 of semiconductor wafer 120 may or may not contain active components and/or passive components, as in a bridge die for the latter case.

An integrated photonic sensitive region 142 is formed in surface 126 for each PIC 150a and PIC 150b. Photonic region 142 is sensitive and responsive to light and converts the information in the light source to electrical signals. Photonic region 142 is applicable to data communications and sensing. In some embodiments, an optical fiber is attached over one or more photonic region 142 using a grating coupler or other suitable means.

An electrically conductive layer 146 is formed over surface 126 and conductive vias 140 using PVD, CVD, electrolytic plating, electroless plating process, or other suitable metal deposition process. Conductive layer 146 can be one or more layers of Al, Cu, Sn, Ni, Au, Ag, or other suitable electrically conductive material. Conductive layer 146 operates as an RDL providing electrical interconnect for conductive vias 140, as well as photonic region 142 and any active electrical components and passive electrical components on surface 126. Portions of conductive layer 146 can be electrically common or electrically isolated depending on the design and function of electrical components attached thereto.

In FIG. 3b, a sacrificial photoresist layer 148 is formed over photonic region 142 to operate as a protective layer for the region during subsequent manufacturing processes or operations. Semiconductor wafer 120 is singulated through saw street 132 using a saw blade or laser cutting tool into individual PIC 150a and 150b, similar to FIG. 2c. The individual PIC 150a-150b can be inspected and electrically tested for identification of KGD/KGU post singulation. FIG. 3c shows PIC 150a or 150b post singulation.

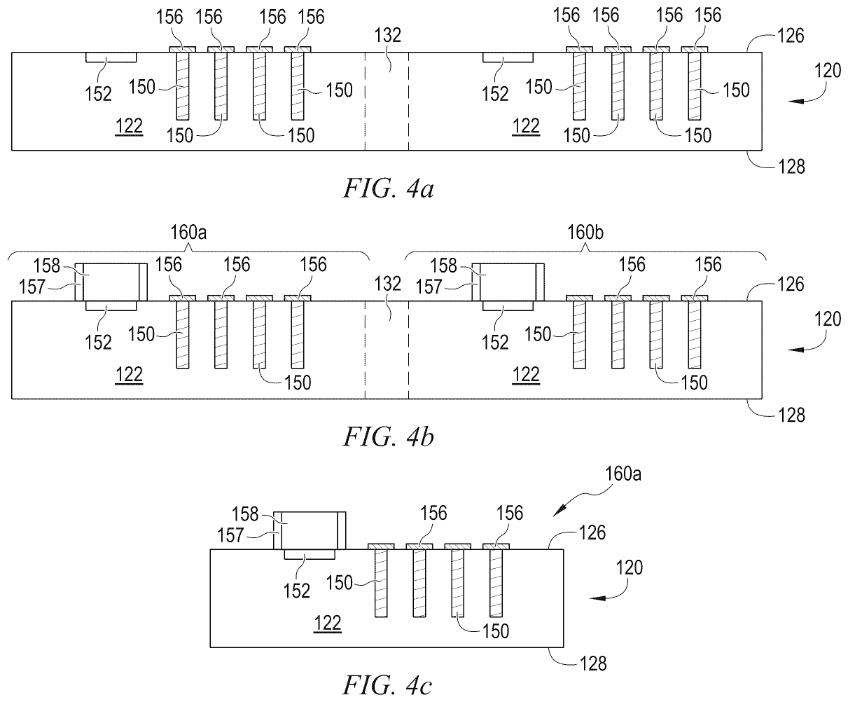

FIGS. 4a-4c illustrate another process of forming a PIC. Continuing from FIG. 2a, a plurality of conductive vias 150 is formed from surface 126 at least partially through base material 122. A plurality of vias is formed at least partially through semiconductor wafer 120 using an etching process or by LDA. The vias are filled with electrically conductive material, such as Al, Cu, Sn, Ni, Au, Ag, or other suitable electrically conductive material, to form conductive vias 150. Components having a similar function are assigned the same reference number. Surface 126 of semiconductor wafer 120 may or may not contain active components and/or passive components, as in a bridge die in the latter case.

A photonic sensitive region 152 is formed in surface 126 for each PIC 160a and PIC 160b. Photonic region 152 is sensitive and responsive to light and converts the information in the light source to electrical signals. Photonic region 152 is applicable to data communications and sensing. In some embodiments, an optical fiber is attached over one or more photonic region 152 using a grating coupler or other suitable means.

An electrically conductive layer 156 is formed over surface 126 and conductive vias 150 using PVD, CVD, electrolytic plating, electroless plating process, or other suitable metal deposition process. Conductive layer 156 can be one or more layers of Al, Cu, Sn, Ni, Au, Ag, or other suitable electrically conductive material. Conductive layer 156 operates as an RDL providing electrical interconnect for conductive vias 150, as well as photonic region 152 and any active electrical components and passive electrical components on surface 126. Portions of conductive layer 156 can be electrically common or electrically isolated depending on the design and function of electrical components attached thereto.

In FIG. 4b, dam 157 is formed around photonic region 152. Dam 157 is filled with epoxy material 158 to cover photonic region 152 as a protective layer for the region during subsequent manufacturing processes or operations. In one embodiment, epoxy material 158 is clear or translucent allowing passage of light to photonic region 152. Semiconductor wafer 120 is singulated through saw street 132 using a saw blade or laser cutting tool into individual PIC 160a and 160b, similar to FIG. 2c. The individual PIC 160a-160b can be inspected and electrically tested for identification of KGD/KGU post singulation. FIG. 4c shows PIC 160a or 160b post singulation.

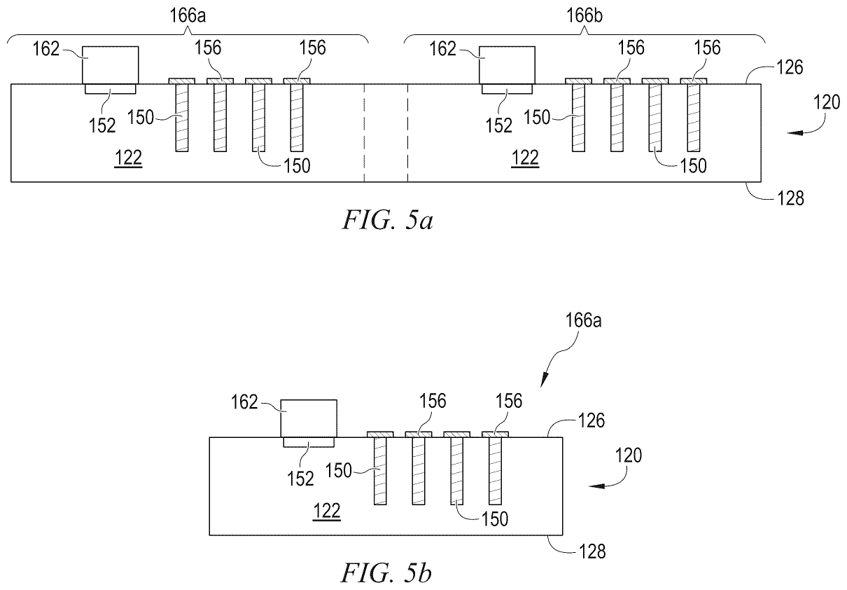

In another embodiment, made similar to FIGS. 4a-4c, FIG. 5a shows prefabricated epoxy block 162 covering photonic region 152 as a protective layer for the region during subsequent manufacturing processes or operations. In one embodiment, prefabricated epoxy block 162 is clear or translucent allowing passage of light to photonic region 152. FIG. 5b shows PIC 166a or 166b post singulation.

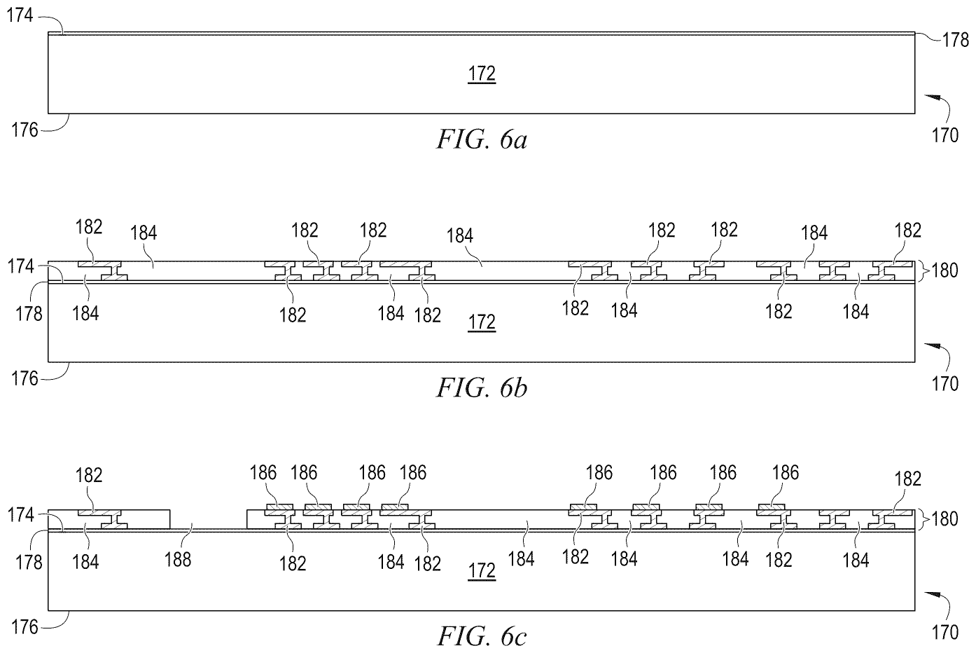

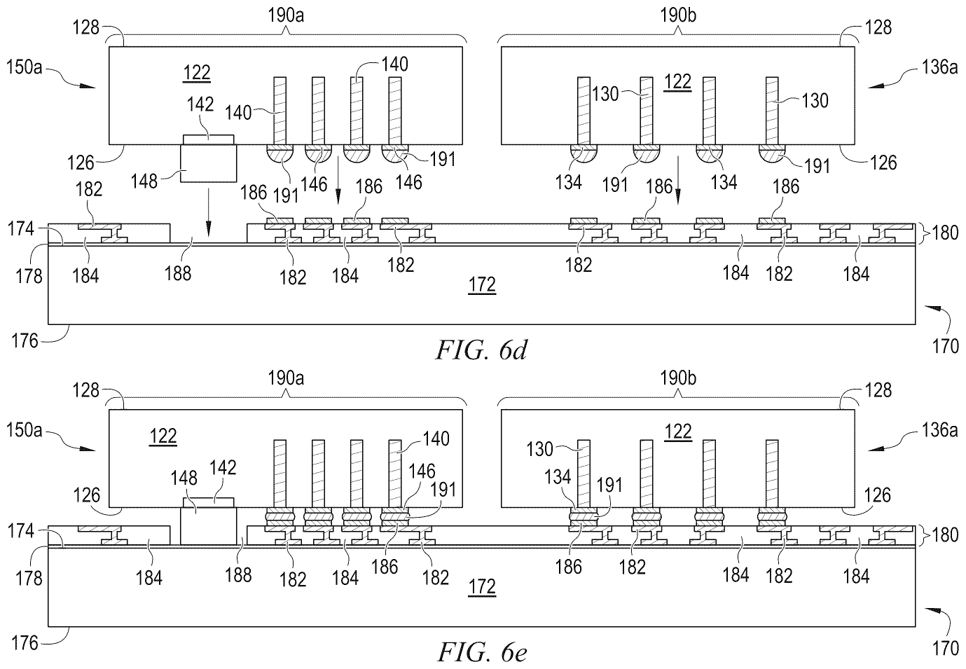

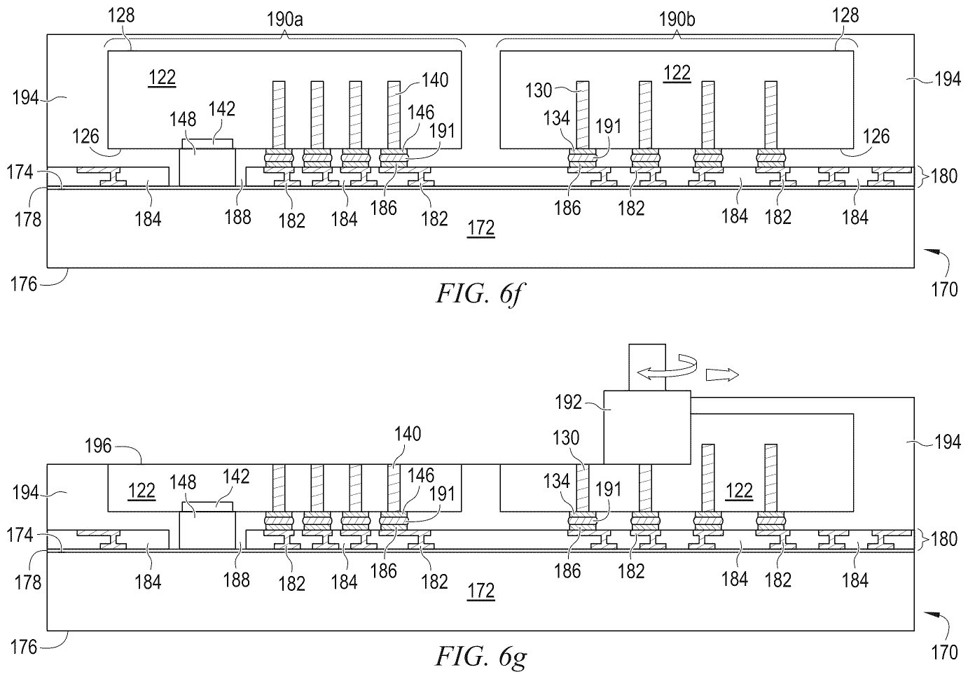

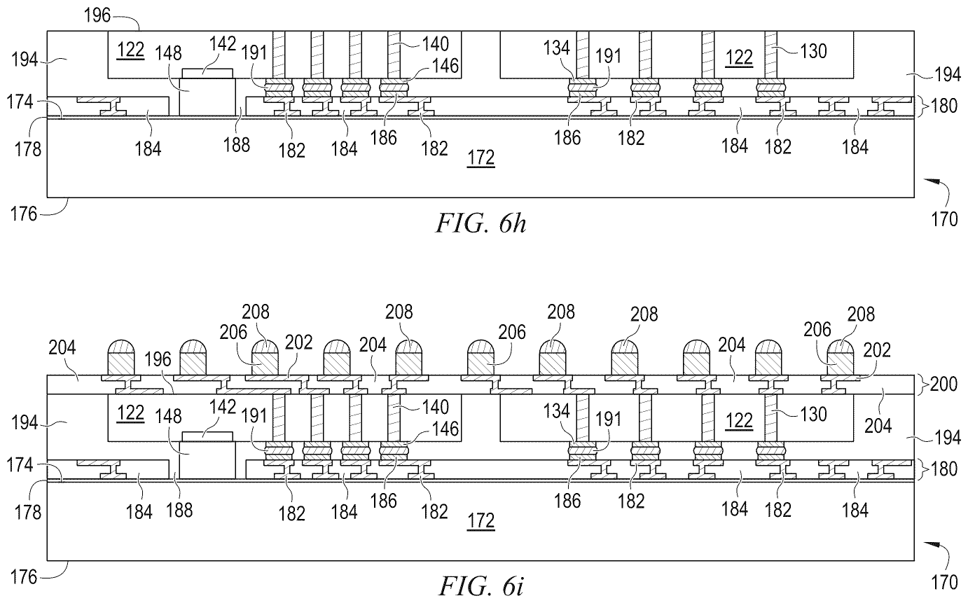

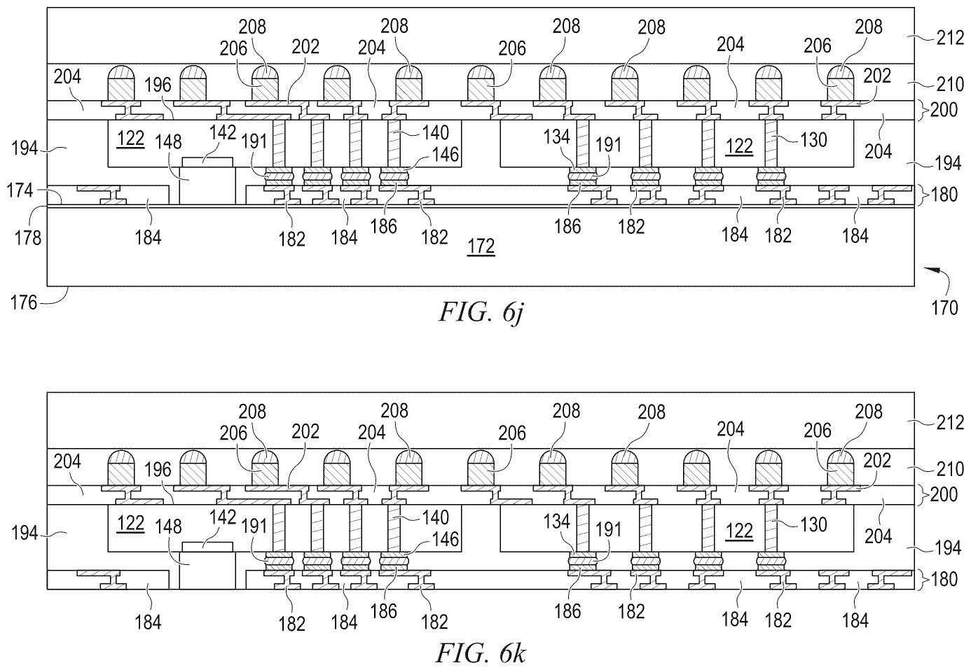

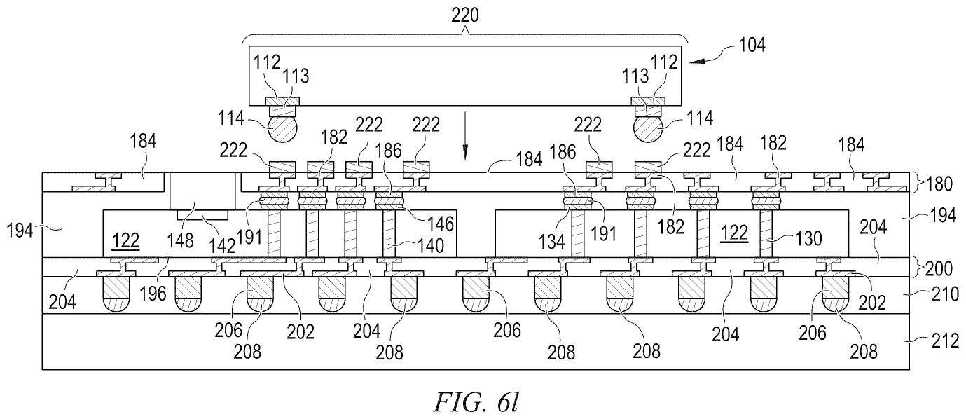

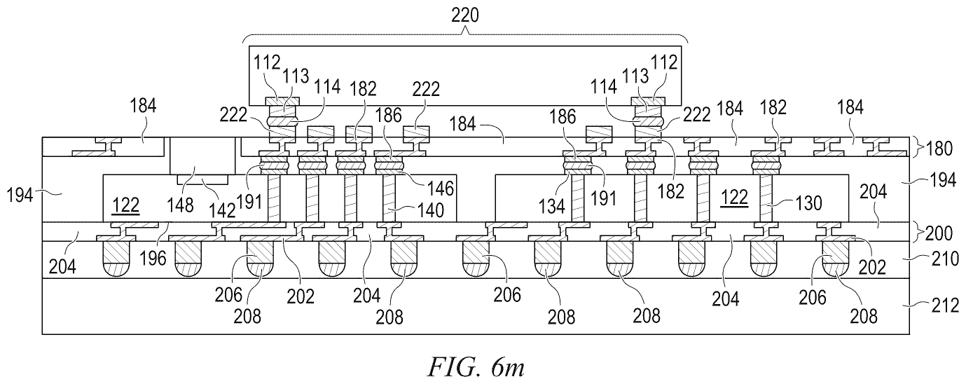

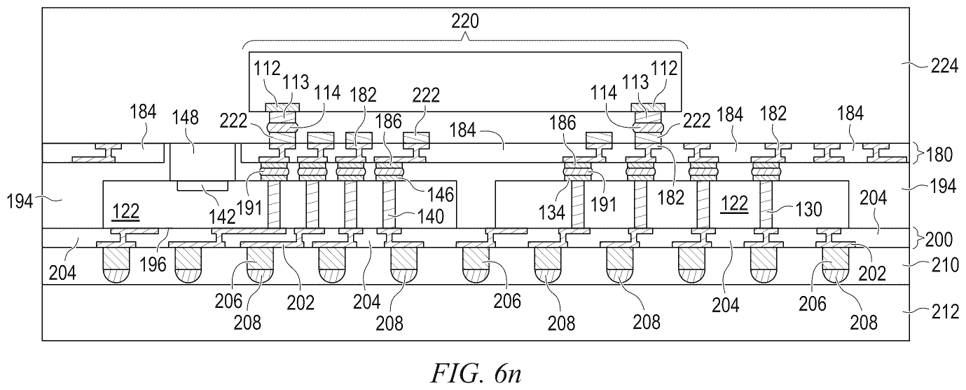

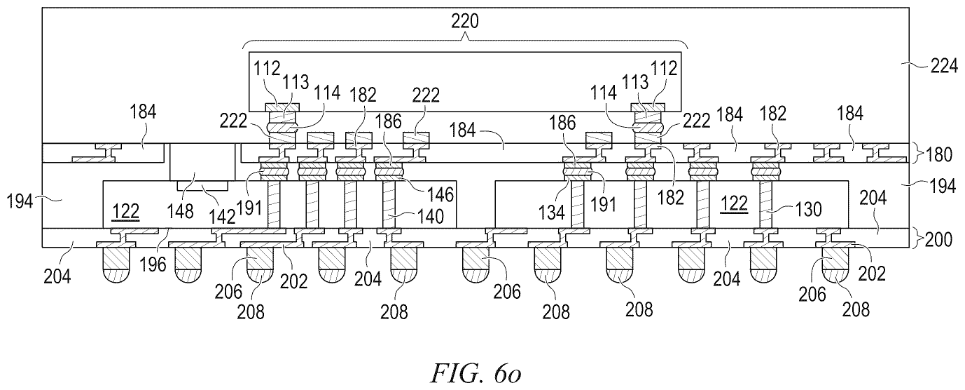

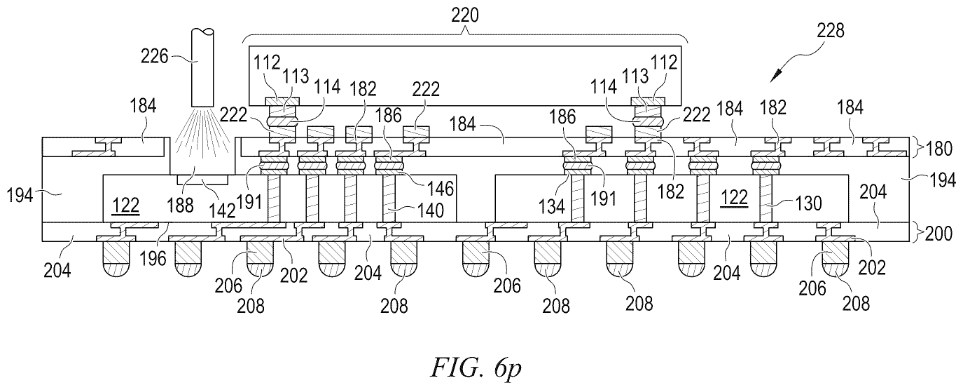

FIG. 6a shows a temporary substrate or carrier 170 containing sacrificial base material 172, such as silicon, polymer, beryllium oxide, glass, metal, or other suitable low-cost, rigid material for structural support. Carrier 170 has major surface 174 and major surface 176, opposite surface 174. In one embodiment, carrier 170 is a support structure with a temporary bonding layer 178 formed over surface 174 of the carrier. Temporary bonding layer 178 can be a double-sided tape.

In FIG. 6b, interconnect structure 180 is formed over surface 174 of carrier 170. Interconnect structure 180 includes one or more conductive layers 182 and one or more insulating layers 184. Conductive layers 182 can be one or more layers of Al, Cu, Sn, Ni, Au, Ag, or other suitable electrically conductive material. Conductive layers 182 can be formed using PVD, CVD, electrolytic plating, electroless plating process, or other suitable metal deposition process. Conductive layers 182 provide horizontal electrical interconnect across interconnect structure 180 and vertical electrical interconnect between the top surface and bottom surface of interconnect structure 180 as an RDL. Portions of conductive layers 182 can be electrically common or electrically isolated depending on the design and function of semiconductor die and other electrical components attached thereto. Insulating layers 184 contain one or more layers of SiO2, Si3N4, SiON, Ta2O5, Al2O3, solder resist, polyimide, BCB, PBO, and other material having similar insulating and structural properties. Insulating layers 184 can be formed using PVD, CVD, printing, lamination, spin coating, spray coating, sintering or thermal oxidation. Insulating layers 184 provide isolation between conductive layers 182. There can be multiple conductive layers like 182 separated by insulating layers 184.

In FIG. 6c, a plurality of conductive pillars or pedestals 186 is formed over interconnect structure 180 and electrically connected to conductive layer 182. Conductive pillars 186 can be formed with a photoresist layer deposited over interconnect structure 180. The photoresist layer is patterned and etched according to the intended locations of conductive pillars 186. The openings in the photoresist layer are filled with electrically conductive material, such as Al, Cu, Sn, Ni, Au, Ag, or other suitable electrically conductive material, to form conductive pillars 186. An opening 188 is also formed in interconnect structure 180.

In FIG. 6d, a plurality of electrical components 190a-190b is disposed over interconnect structure 180. Electrical components 190a-190b are each positioned over interconnect structure 180 using a pick and place operation. In one embodiment, electrical component 190a is selected as PIC 150a from FIG. 3c. In this case, photoresist layer 148 and photonic region 142 are aligned with opening 188 and conductive layer 146 is aligned with conductive pillars 186. Alternatively, electrical component 190a can be PIC 160a from FIG. 4c or PIC 166a from FIG. 5b. In this case, epoxy 158 or prefabricated epoxy block 162 and photonic region 152 are aligned with opening 188 and conductive layer 156 is aligned with conductive pillars 186. In one embodiment, electrical component 190b is selected as interconnect component/bridge die 136a from FIG. 2d. Conductive layer 134 is aligned with conductive pillars 186.

Electrical components 190a-190b are brought into contact with interconnect structure 180 and bonded to conductive layer 182 with conductive paste or bumps 191. FIG. 6e illustrates electrical components 190a-190b electrically and mechanically connected to conductive pillars 186 and conductive layers 182 of interconnect structure 180. Photoresist layer 148 is disposed within opening 188 and covers photonic region 142.

In FIG. 6f, encapsulant or molding compound 194 is deposited over and around electrical components 190a-190b and interconnect structure 180 using a paste printing, compressive molding, transfer molding, liquid encapsulant molding, vacuum lamination, spin coating, or other suitable applicator. Encapsulant 194 can be polymer composite material, such as epoxy resin with filler, epoxy acrylate with filler, or polymer with proper filler. Encapsulant 194 is non-conductive, provides structural support, and environmentally protects the semiconductor device from external elements and contaminants.

In FIG. 6g, a portion of encapsulant 194 and electrical components 190a-190b are removed by grinder 192. The grinding operation planarizes surface 196 of encapsulant 194 and electrical components 190a-190b and exposes conductive vias 130 and conductive vias 140. FIG. 6h shows the assembly post grinding.

In FIG. 6i, interconnect structure 200 is formed over surface 196 of encapsulant 194 and electrical components 190a-190b post grinding with conductive vias 130 and 140 exposed. Interconnect structure 200 includes one or more conductive layers 202 and one or more insulating layers 204. Conductive layers 202 can be one or more layers of Al, Cu, Sn, Ni, Au, Ag, or other suitable electrically conductive material. Conductive layers 202 can be formed using PVD, CVD, electrolytic plating, electroless plating process, or other suitable metal deposition process. Conductive layers 202 provide horizontal electrical interconnect across interconnect structure 200 and vertical electrical interconnect between the top surface and bottom surface of interconnect structure 200 as an RDL. Portions of conductive layers 202 can be electrically common or electrically isolated depending on the design and function of semiconductor die and other electrical components attached thereto. Insulating layers 204 contains one or more layers of SiO₂, Si3N4, SiON, Ta2O5, Al2O3, solder resist, polyimide, BCB, PBO, and other material having similar insulating and structural properties. Insulating layers 204 can be formed using PVD, CVD, printing, lamination, spin coating, spray coating, sintering or thermal oxidation. Insulating layers 204 provides isolation between conductive layers 202. There can be multiple conductive layers like 202 separated by insulating layers 204.

A plurality of conductive pillars or pedestals 206 is formed over interconnect structure 200 and electrically connected to conductive layer 202. Conductive pillars 206 can be formed with a photoresist layer deposited over interconnect structure 200. The photoresist layer is patterned and etched according to the intended locations of conductive pillars 206. The openings in the photoresist layer are filled with electrically conductive material, such as Al, Cu, Sn, Ni, Au, Ag, or other suitable electrically conductive material, to form conductive pillars 206.

An electrically conductive bump material is deposited over conductive pillars 206 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive pillars 206 using a suitable attachment or bonding process. In one embodiment, the bump material is reflowed by heating the material above its melting point to form balls or bumps 208. In one embodiment, bump 208 is formed over an under bump metallization (UBM) having a wetting layer, barrier layer, and adhesive layer. Bump 208 can also be compression bonded or thermocompression bonded to conductive pillar 206. Bump 208 represents one type of interconnect structure that can be formed over conductive pillar 206. The interconnect structure can also use bond wires, conductive paste, stud bump, micro bump, or other electrical interconnect.

In FIG. 6j, temporary carrier 212 and bonding layer 210 are applied over interconnect structure 200, conductive pillars 206, and bumps 208, as disposed on carrier 170. Temporary carrier 212 and bonding layer 210 can be a hybrid material including a glass carrier and a thick adhesive layer or release material layer sufficient to cover conductive pillars 206 and bumps 208. In FIG. 6k, temporary carrier 170 and bonding layer 178 are removed by chemical etching, chemical mechanical polishing (CMP), mechanical peel-off, mechanical grinding, thermal bake, ultra-violet (UV) light, or wet stripping to expose interconnect structure 180. Temporary carrier 212 and bonding layer 210 supports the assembly during carrier 170 removal and in preparation for removal of photoresist layer 148 and electrical component 220 flip chip attachment to interconnect structure 180.

In FIG. 6l, the assembly is inverted and a plurality of conductive pillars or pedestals 222 is formed over interconnect structure 180 and electrically connected to conductive layer 182. Conductive pillars 222 can be formed with a photoresist layer deposited over interconnect structure 180. The photoresist layer is patterned and etched according to the intended locations of conductive pillars 222. The openings in the photoresist layer are filled with electrically conductive material, such as Al, Cu, Sn, Ni, Au, Ag, or other suitable electrically conductive material, to form conductive pillars 222.

One or more electrical components 220 is disposed over interconnect structure 180. Electrical component(s) 220 are each positioned over interconnect structure 180 using a pick and place operation. In one embodiment, electrical component 220 can be semiconductor die 104 from FIG. 1c. Alternatively, electrical component 220 can include other semiconductor die, semiconductor packages, surface mount devices, discrete electrical devices, or IPDs. Electrical component 220 is brought into contact with and bonded to conductive pillars 222 with conductive paste or bumps 114. FIG. 6m illustrates electrical component 220 electrically and mechanically connected to conductive pillars 222 and conductive layers 182 of interconnect structure 180.

In FIG. 6n, dicing tape or other support film 224 is applied over electrical component 220 and interconnect structure 180. In FIG. 60, temporary carrier 212 and bonding layer 210 are removed. Dicing tape or other support film 224 supports the assembly as temporary carrier 212 and bonding layer 210 are removed.

In FIG. 6p, dicing tape or other support film 224 is removed. Photoresist layer 148 is removed to expose photonic region 142. Photoresist layer 148 provides protection for photonic region 142 during the above manufacturing processes or operations. For example, photoresist layer 148 prevents encapsulant 194 from reaching photonic region 142 during encapsulation. Photoresist layer 148 prevents contamination of photonic region 148 during attachment of electrical components and formation of various interconnect structures. After removal of photoresist layer 148, photonic region 142 can now operate, with high reliability, without any damage or contamination from the above manufacturing processes or operations. Light source 226 emits light through opening 188 in interconnect structure 180 for normal operation of PIC in FOI package 228.

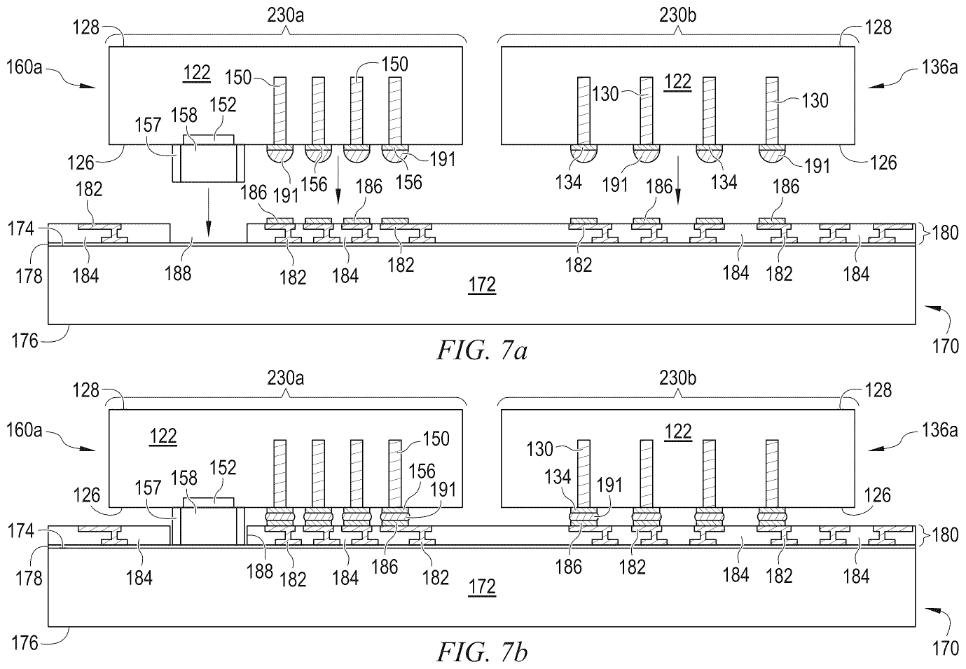

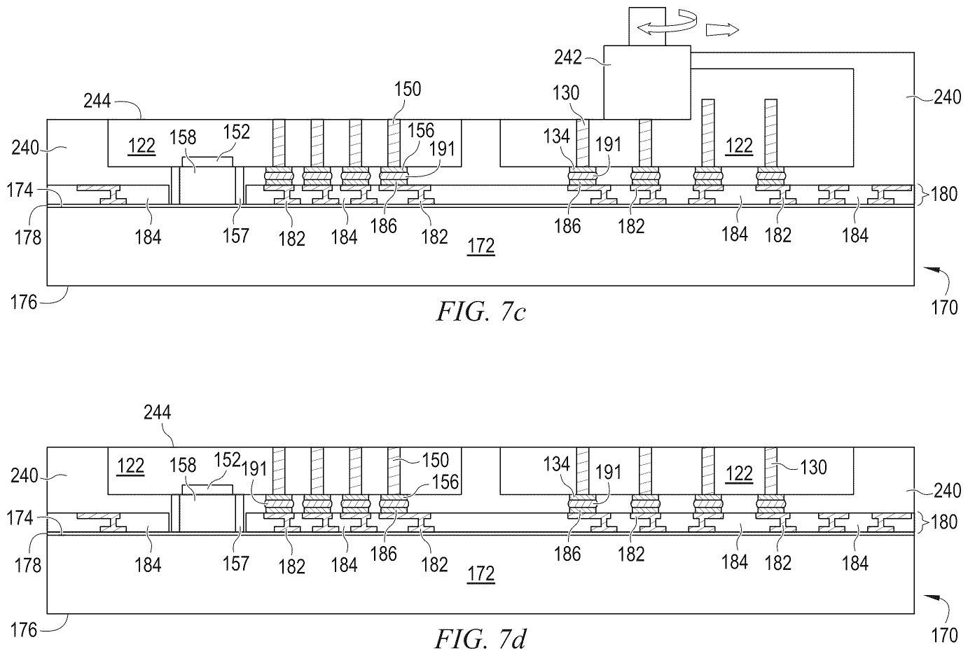

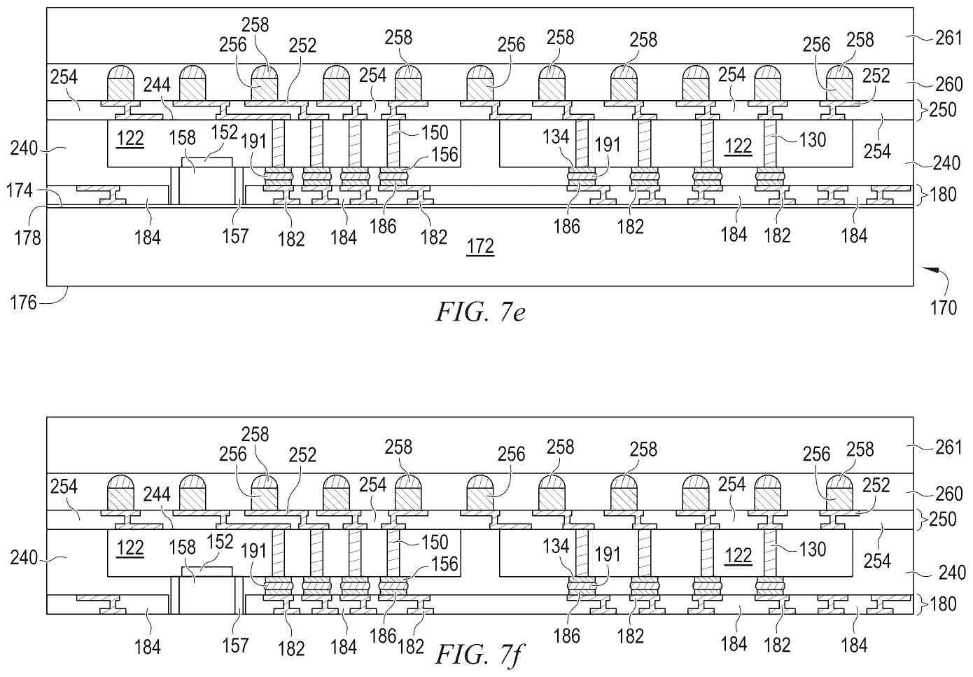

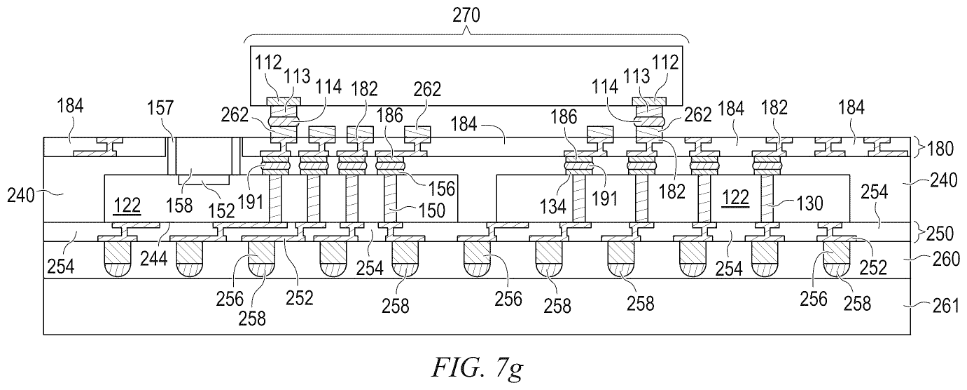

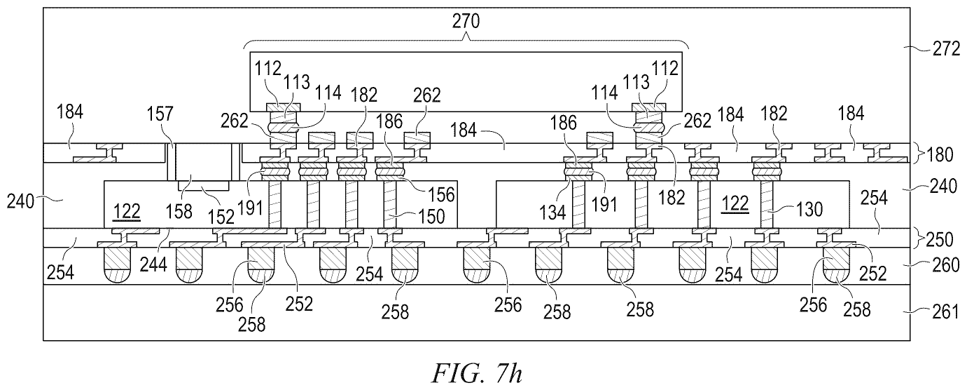

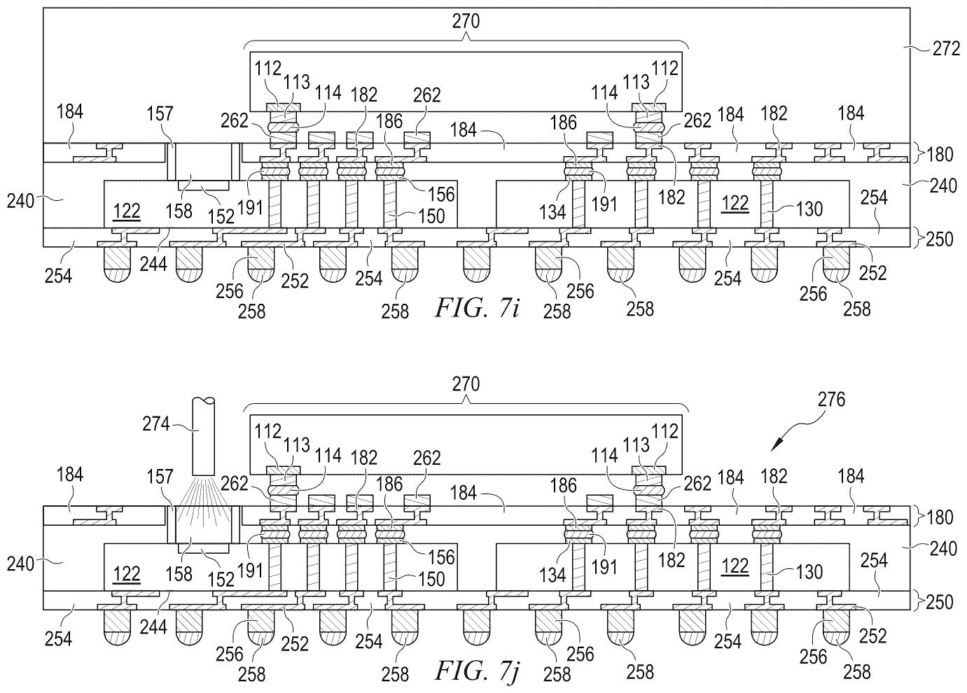

In another embodiment, continuing from FIG. 6c, a plurality of electrical components 230a-230b is disposed over interconnect structure 180, as shown in FIG. 7a. Electrical components 230a-230b are each positioned over interconnect structure 180 using a pick and place operation. In one embodiment, electrical component 230a is selected as PIC 160a from FIG. 4c. In this case, epoxy 158 and photonic region 152 are aligned with opening 188 and conductive layer 156 is aligned with conductive pillars 186. Electrical component 230b can be selected as interconnect component/bridge die 136b from FIG. 2d. Conductive layer 134 is aligned with conductive pillars 186.

Electrical components 230a-230b are brought into contact with interconnect structure 180 and bonded to conductive layer 182 with conductive paste or bumps 232. FIG. 7b illustrates electrical components 230a-230b electrically and mechanically connected to conductive pillars 186 and conductive layers 182 of interconnect structure 180. Epoxy 158 is disposed within opening 188 and covers photonic region 152 to protect the region during subsequent manufacturing processes or operations.

In FIG. 7c, encapsulant or molding compound 240 is deposited over and around electrical components 230a-230b and interconnect structure 180 using a paste printing, compressive molding, transfer molding, liquid encapsulant molding, vacuum lamination, spin coating, or other suitable applicator, similar to FIG. 6f. Encapsulant 240 can be polymer composite material, such as epoxy resin with filler, epoxy acrylate with filler, or polymer with proper filler. Encapsulant 240 is non-conductive, provides structural support, and environmentally protects the semiconductor device from external elements and contaminants.

A portion of encapsulant 240 and electrical components 230a-230b are removed by grinder 242. The grinding operation planarizes surface 244 of encapsulant 240 and electrical components 230a-230b and exposes conductive vias 130 and conductive vias 150. FIG. 7d shows the assembly post grinding.

In FIG. 7e, interconnect structure 250 is formed over surface 244 of encapsulant 240 and electrical components 230a-230b post grinding with conductive vias 130 and 150 exposed. Interconnect structure 250 includes one or more conductive layers 252 and one or more insulating layers 254. Conductive layers 252 can be one or more layers of Al, Cu, Sn, Ni, Au, Ag, or other suitable electrically conductive material. Conductive layers 252 can be formed using PVD, CVD, electrolytic plating, electroless plating process, or other suitable metal deposition process. Conductive layers 252 provide horizontal electrical interconnect across interconnect structure 250 and vertical electrical interconnect between the top surface and bottom surface of interconnect structure 250 as an RDL. Portions of conductive layers 252 can be electrically common or electrically isolated depending on the design and function of semiconductor die and other electrical components attached thereto.

Insulating layers 254 contain one or more layers of SiO2, Si3N4, SiON, Ta2O5, Al2O3, solder resist, polyimide, BCB, PBO, and other material having similar insulating and structural properties. Insulating layers 254 can be formed using PVD, CVD, printing, lamination, spin coating, spray coating, sintering or thermal oxidation. Insulating layers 254 provide isolation between conductive layers 252. There can be multiple conductive layers like 252 separated by insulating layers 254.

A plurality of conductive pillars or pedestals 256 is formed over interconnect structure 250 and electrically connected to conductive layer 252. Conductive pillars 256 can be formed with a photoresist layer deposited over interconnect structure 250. The photoresist layer is patterned and etched according to the intended locations of conductive pillars 256. The openings in the photoresist layer are filled with electrically conductive material, such as Al, Cu, Sn, Ni, Au, Ag, or other suitable electrically conductive material, to form conductive pillars 256.

An electrically conductive bump material is deposited over conductive pillars 256 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive pillars 256 using a suitable attachment or bonding process. In one embodiment, the bump material is reflowed by heating the material above its melting point to form balls or bumps 258. In one embodiment, bump 258 is formed over a UBM having a wetting layer, barrier layer, and adhesive layer. Bump 258 can also be compression bonded or thermocompression bonded to conductive pillar 256. Bump 258 represents one type of interconnect structure that can be formed over conductive pillar 256. The interconnect structure can also use bond wires, conductive paste, stud bump, micro bump, or other electrical interconnect.

In FIG. 7f, temporary carrier 261 and bonding layer 260 are applied over interconnect structure 250, conductive pillars 256, and bumps 258. Temporary carrier 261 and bonding layer 260 can be a hybrid material including a glass carrier and a thick adhesive layer or release material layer sufficient to cover conductive pillars 256 and bumps 258. Temporary carrier 170 and bonding layer 178 are removed by chemical etching, CMP, mechanical peel-off, mechanical grinding, thermal bake, UV light, or wet stripping to expose interconnect structure 180, similar to FIGS. 6j-6k. Temporary carrier 261 and bonding layer 260 support the assembly during carrier 170 removal and in preparation for attachment of electrical component 280 to interconnect structure 180.

In FIG. 7g, the assembly is inverted and a plurality of conductive pillars or pedestals 262 is formed over interconnect structure 180 and electrically connected to conductive layer 182. Conductive pillars 262 can be formed with a photoresist layer deposited over interconnect structure 180. The photoresist layer is patterned and etched according to the intended locations of conductive pillars 262. The openings in the photoresist layer are filled with electrically conductive material, such as Al, Cu, Sn, Ni, Au, Ag, or other suitable electrically conductive material, to form conductive pillars 262.

One or more electrical components 270 is disposed over interconnect structure 180, similar to FIGS. 6l-6m. Electrical component(s) 270 are each positioned over interconnect structure 180 using a pick and place operation. In one embodiment, electrical component 270 can be semiconductor die 104 from FIG. 1c. Alternatively, electrical component 270 can include other semiconductor die, semiconductor packages, surface mount devices, discrete electrical devices, or IPDs. Electrical component 270 is brought into contact with and bonded to conductive pillar 262 with conductive paste or bumps 114. FIG. 7g illustrates electrical component 270 electrically and mechanically connected to conductive pillars 262 and conductive layers 182 of interconnect structure 180.

In FIG. 7h, dicing tape or other support film 272 is applied over electrical component 270 and interconnect structure 180. In FIG. 7i, temporary carrier 261 and bonding layer 260 are removed. Dicing tape or other support film 272 supports the assembly as temporary carrier 261 and bonding layer 260 are removed.

In FIG. 7j, dicing tape or other support film 272 is removed to expose clear or translucent epoxy material 158. Clear or translucent epoxy material 158 within dam 157 provides protection for photonic region 152 during the manufacturing processes or operations of FIGS. 7a-7j. For example, epoxy 158 prevents encapsulant 240 from reaching photonic region 152 during encapsulation. Clear or translucent epoxy material 158 within dam 157 prevents contamination of photonic region 148 during attachment of electrical components and formation of various interconnect structures. Photonic region 142 can now operate, with high reliability, without any damage or contamination from the manufacturing processes or operations. Light source 274 emits light through clear or translucent epoxy material 158 for normal operation of PIC in FOI package 276.

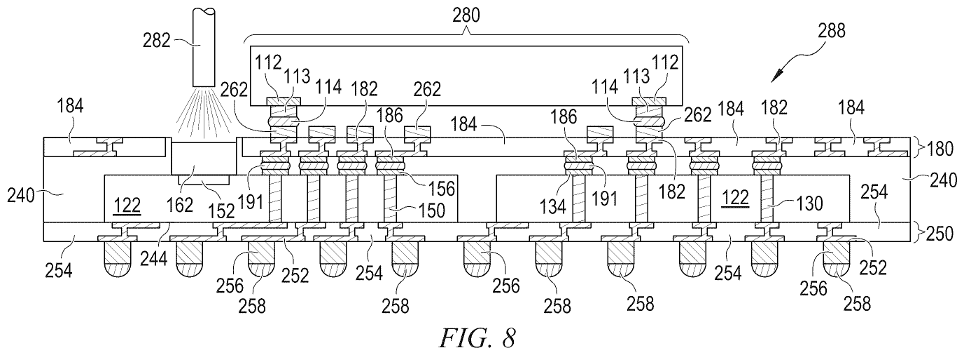

FIG. 8 illustrates another embodiment, similar to FIG. 7h, with clear or translucent, prefabricated epoxy block 162 over photonic region 152. Clear or translucent, prefabricated block 162 provides protection for photonic region 152 during the manufacturing processes or operations, as described in FIGS. 7a-7j. Photonic region 152 is exposed to light source 282 through clear or translucent epoxy block 162 for normal operation of PIC in FOI package 288.

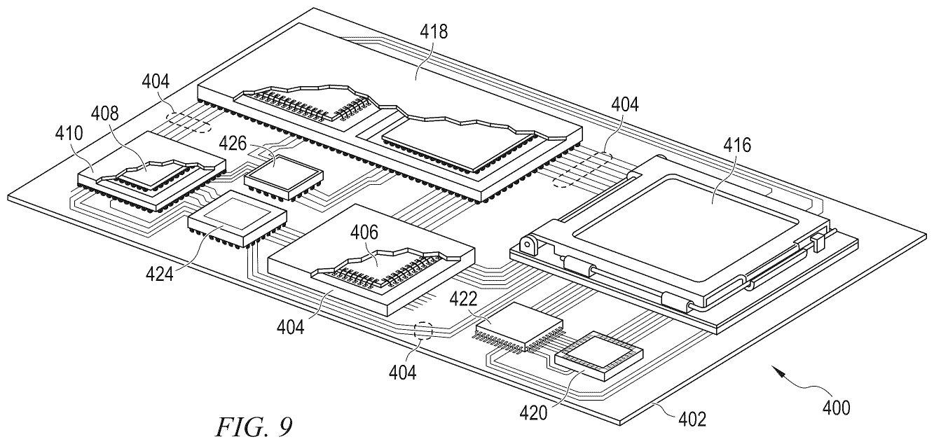

FIG. 9 illustrates electrical device 400 having a chip carrier substrate or PCB 402 with a plurality of semiconductor packages disposed on a surface of PCB 402, including PIC in FOI packages 228, 276, and 288. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 9, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a first interconnect structure including an opening in the first interconnect structure;
a photonic integrated circuit (PIC) disposed over the first interconnect structure with a photonic region aligned with the opening in the first interconnect structure;
a second interconnect structure disposed over the PIC; and
a protective layer disposed within the opening over the photonic region.

2. The semiconductor device of claim 1, further including an interconnect component comprising a plurality of conductive vias disposed over the first interconnect structure.

3. The semiconductor device of claim 1, further including a plurality of conductive vias formed at least partially through the PIC.

4. The semiconductor device of claim 1, further including an electrical component disposed over the second interconnect structure.

5. The semiconductor device of claim 1, wherein the protective layer includes:
a dam formed over the PIC; and
an epoxy material disposed within the dam over the photonic region.

6. The semiconductor device of claim 1, wherein the protective layer includes an epoxy material disposed over the photonic region.

7. A semiconductor device, comprising:
a first interconnect structure;
a photonic integrated circuit (PIC) disposed over the first interconnect structure with a photonic region aligned with an opening in the first interconnect structure; and
a protective layer disposed within the opening over the photonic region.

8. The semiconductor device of claim 7, further including a second interconnect structure disposed over the PIC.

9. The semiconductor device of claim 8, further including an electrical component disposed over the second interconnect structure.

10. The semiconductor device of claim 7, further including an interconnect component comprising a plurality of conductive vias disposed over the first interconnect structure.

11. The semiconductor device of claim 7, further including a plurality of conductive vias formed at least partially through the PIC.

12. The semiconductor device of claim 7, wherein the protective layer includes:
a dam formed over the PIC; and
an epoxy material disposed within the dam over the photonic region.

13. The semiconductor device of claim 7, wherein the protective layer includes an epoxy material disposed over the photonic region.

14. A method of making a semiconductor device, comprising:
providing a first interconnect structure including an opening in the first interconnect structure;
disposing a photonic integrated circuit (PIC) over the first interconnect structure with a photonic region aligned with the opening in the first interconnect structure;
disposing a second interconnect structure over the PIC; and
disposing a protective layer within the opening over the photonic region.

15. The method of claim 14, further including disposing an interconnect component comprising a plurality of conductive vias over the first interconnect structure.

16. The method of claim 14, further including forming a plurality of conductive vias at least partially through the PIC.

17. The method of claim 14, further including disposing an electrical component over the second interconnect structure.

18. The method of claim 14, wherein disposing the protective layer includes:
forming a dam over the PIC; and
disposing an epoxy material within the dam over the photonic region.

19. The method of claim 14, wherein disposing the protective layer includes disposing an epoxy material over the photonic region.

20. A method of making a semiconductor device, comprising:
providing a first interconnect structure;
disposing a photonic integrated circuit (PIC) over the first interconnect structure with a photonic region aligned with an opening in the first interconnect structure; and
disposing a protective layer within the opening over the photonic region.

21. The method of claim 20, further including disposing a second interconnect structure over the PIC.

22. The method of claim 21, further including disposing an electrical component over the second interconnect structure.

23. The method of claim 20, further including disposing an interconnect component comprising a plurality of conductive vias over the first interconnect structure.

24. The method of claim 20, further including forming a plurality of conductive vias at least partially through the PIC.

25. The method of claim 20, wherein disposing the protective layer includes disposing an epoxy material over the photonic region.
